(19) United States
(12) Patent Application Publication
(10) Pub. No.: US 2015/0137792 A1
(43) Pub. Date: May 21, 2015

(54) POWER CONSUMPTION MONITORING APPARATUS

(71) Applicant: KONINKLIJKE PHILIPS N.V., EINDHOVEN (NL)

(72) Inventors: Alessio Filippi, Eindhoven (NL); Ying Wang, Eindhoven (NL); Ronald Rietman, Eindhoven (NL); Ercan Ferit Gigi, Eindhoven (NL)

(21) Appl. No.: 14/408,821

(22) PCT Filed: Jun. 20, 2013
(86) PCT No.: PCT/IB2013/055069

§ 371 Date: Dec. 17, 2014

Related U.S. Application Data
(60) Provisional application No. 61/665,980, filed on Jun. 29, 2012.

(51) Int. Cl. G01D 4/00; G01R 21/133

(52) U.S. Cl. CPC G01D 4/00; G01R 21/133
USPC 324/76.11

(57) ABSTRACT

The invention relates to a power consumption monitoring apparatus (11) for monitoring the power consumed in a network (1) of electrical devices (3, 4, 5; 6, 7, 8). An electrical parameter measuring unit measures an overall electrical parameter of the network over time,a group signature providing unit provides group signatures, wherein each group signature is indicative of an electrical parameter of a certain group (9; 10) of electrical devices over time, and a disaggregation unit disaggregates the measured overall electrical parameter over time for determining the power consumption of the individual groups of electrical devices depending on the provided group signatures. This allows disaggregating the overall electrical parameter, without providing for each group an individual measuring unit, thereby reducing the required hardware and the time needed for installing and maintaining the power consumption monitoring apparatus.

### FIELD OF THE INVENTION

The invention relates to a power consumption monitoring apparatus, a power consumption monitoring method and a power consumption monitoring computer program for monitoring the power consumed in a network of electrical devices. The invention relates further to a signature determination apparatus, a signature determination method and a signature determination computer program for determining signatures to be used by the power consumption monitoring apparatus.

### BACKGROUND OF THE INVENTION

In sub-metering power consumption monitoring systems for determining the power consumed by different groups of electrical devices a measuring unit is used per group of electrical devices, in order to monitor the power consumed by the respective group.

Providing each group of electrical devices with a measuring unit renders the sub-metering power consumption monitoring apparatus technically relatively complex, wherein a lot of hardware is required and, thus, installation and maintenance of the apparatus take a relatively long time.

### SUMMARY OF THE INVENTION

It is an object of the present invention to provide a power consumption monitoring apparatus, a power consumption monitoring method and a power consumption monitoring computer program for monitoring the power consumed in a network of electrical devices, wherein the hardware required for performing the monitoring can be reduced.

In a first aspect of the present invention a power consumption monitoring apparatus for monitoring the power consumed in a network of electrical devices is presented, wherein the power consumption monitoring apparatus comprises:
an electrical parameter measuring unit for measuring an overall electrical parameter of the network over time,
a group signature providing unit for providing group signatures, wherein each group signature is indicative of an electrical parameter of a certain group of electrical devices over time,
a disaggregation unit for disaggregating the measured overall electrical parameter over time for determining the power consumption of the individual groups of electrical devices depending on the provided group signatures.

Since the disaggregation unit disaggregates the measured overall electrical parameter over time for determining the power consumption of the individual groups of electrical devices depending on the provided group signatures, it is not necessary to provide for each group of electrical devices an individual measuring unit, thereby reducing the hardware required for performing the power consumption monitoring. Moreover, since it is not required to provide each group of electrical devices with a separate measuring unit, the time needed for installing and maintaining the power consumption monitoring apparatus can be reduced.

The power consumption monitoring apparatus uses preferentially a non-intrusive load monitoring (NILM) technique for the disaggregation, i.e. for the sub-metering application, to separate different electrical groups, rather than individual appliances, i.e. rather than individual electrical devices.

It is preferred that each group of electrical devices contains a certain kind of electrical devices, wherein different groups contain different kinds of electrical devices. For instance, a first group can comprise light sources of a building only and a second group can comprise the other electrical devices of the building, which consume more power than a light source, like elevators, heating, ventilation and air conditioning (HVAC) devices et cetera.

It is further preferred that the electrical parameter measuring unit is adapted to measure the overall electrical parameter at a single point of measurement, wherein the disaggregation unit is adapted to disaggregate the measured overall electrical parameter measured at the single point of measurement.

It is also preferred that the electrical devices are powered by using alternating current (AC) voltage defining AC periods, wherein the group signatures are indicative of the electrical parameter over an AC period and wherein the disaggregation unit is adapted to determine the power consumed in an AC period by disaggregating the measured overall electrical parameter over the AC period depending on the provided group signatures. This allows disaggregating the electrical parameter measured over time with respect to the different groups of electrical devices in a very reliable way.

The disaggregation unit can be adapted to disaggregate the measured overall electrical parameter by combining group signatures of different groups such that a deviation between a resulting combination of group signatures and the measured overall electrical parameter is minimized. For instance, the combination of the group signatures of the different groups can be an integer linear combination, wherein the integer linear combination can be determined such that a deviation measure applied to the integer linear combination and the measured overall electrical parameter yields a minimized deviation. The deviation measure is, for instance, a squared difference between the measured overall electrical parameter and the integer linear combination, wherein differences between corresponding electrical parameter values of the respective integer linear combination and the measured overall electrical parameter can be calculated, squared and summed for determining the deviation. Corresponding electrical parameter values are, for instance, values that have the same temporal position within an AC period. Based on the combination of group signatures, which minimizes the deviation, the disaggregation unit can easily determine the power consumption of the respective group of electrical devices. For example, if the group signatures represent an electrical current over an AC period, a respective group signature, which is part of the resulting combination that minimizes the deviation, multiplied by the respective linear coefficient can be multiplied with the AC voltage for determining the power consumption of the respective group of electrical devices. This allows disaggregating the measured overall electrical parameter reliably and in a technically relatively simple way.

A group signature is preferentially indicative of the states of the electrical devices of the respective group. A state of an electrical device is, for example, a switched on state, a switched off state, a standby state et cetera. The group signature depends on the states of the different electrical devices of a group, i.e. a group can comprise several group signatures which correspond to different combinations of states of the electrical devices of the respective group. A group signature is therefore not indicative of the state of the individual devices, but only of a combination of the states of the electrical devices of the respective group, i.e. a group could also be regarded as being a multi-state appliance.

The electrical parameter measured over time is preferentially the electrical current.

In a further aspect of the present invention a signature determination apparatus for determining signatures to be used by a power consumption monitoring apparatus is presented, wherein the signature determination apparatus comprises:
an electrical parameter measuring unit for measuring an electrical parameter over time separately for different groups of electrical devices of a network of electrical devices, in order to measure for each group the electrical parameter over time,
a group signature determination unit for determining group signatures for the groups of electrical devices based on the electrical parameter measured over time for the respective group of electrical devices.

The determined group signatures may be stored in a storing unit, in particular a database, wherein the stored group signatures can be provided to the power consumption monitoring apparatus for allowing the power consumption monitoring apparatus to disaggregate the measured overall power consumption based on the provided group signatures.

The electrical devices of the network are preferentially powered by using AC voltage defining AC periods, wherein the electrical parameter measuring unit is adapted to measure for each group the electrical parameter over the AC periods, in order to determine for each group current cycles which correspond to an AC period, wherein the group signature determination unit is adapted to determine the group signatures of a group from the current cycles measured for the respective group. This allows determining the group signatures such that they can relatively easily be compared with a measured overall electrical parameter of the network of electrical devices for disaggregation purposes.

The group signature determination unit is preferentially adapted to select from the current cycles, which have been measured for the respective group, current cycles, which should be used for determining the group signatures for the respective group, depending on differences between the current cycles measured for the respective group. In particular, the group signature determination unit is adapted to select the current cycles to be used for determining the group signatures for the respective group such that for each current cycle measured for the respective group the difference between the respective measured current cycle and at least one selected current cycle is smaller than a difference threshold. For instance, if each current cycle is sampled with K samples per AC period, each measured current cycle of a respective group can be seen as a point in a corresponding K-dimensional space. If a large number of N current cycles have been measured for a respective group of electrical devices, these measured current cycles may correspond to N distinct points in the K-dimensional space, even if the network of electrical devices is stable, because of measurement noise. In order to reduce this large number of measured current cycles, the group signature determination unit preferentially selects a smaller number of current cycles to be used for determining the group signatures. For example, in the K-dimensional space, the concept of distance between points can be introduced, wherein the Euclidean distance is preferred. Given a difference threshold E, a set of points S can be determined, for example, as follows. The N measured current cycles can be denoted by C₁ . . . C_{N}. The set of points S can be initialized to be an empty set and initially a variable n can be set to one. Then, considering Cₙ, it can be searched for the point in the set of points S, which is closest to the current cycle Cₙ. If such a closest point exists in the set of points S and if its distance to the current cycle Cₙ is less than the difference threshold E, the set of points S is not modified, otherwise the current cycle Cₙ is added to the set of points S. The variable n is then incremented by one and these steps are repeated, until all measured current cycles C₁. . . Cₙ have been considered. The group signature determination unit can further be adapted to compare the resulting number of points in the set of points S with a predefined number threshold and to repeat the entire procedure of selecting the current cycles from all measured current cycles with a larger difference threshold E for reducing the number of group signatures determined for a respective group.

In this selection procedure, it is assumed that a point X in the K-dimensional space represents a current cycle C well enough, if the distance between the points X and C is less than the difference threshold E. The difference threshold E may be selected depending on the desired accuracy of recognizing a current cycle, i.e. of the disaggregation procedure, and depending on the desired number of group signatures per respective group of electrical devices. The difference threshold can therefore be selected such that it provides a satisfactory trade-off between the accuracy of disaggregation and the computational efforts needed for performing the disaggregation.

The group signature determination unit can be adapted to divide the measured current cycles by the AC voltage, wherein in this case, during the disaggregation, also the measured overall electrical current is divided by the AC voltage, in order to deal with possible voltage variations, thereby allowing for an improvement of the accuracy of the disaggregation.

The power consumption monitoring apparatus and the signature determination apparatus can be integrated in a single apparatus. For instance, the power consumption monitoring apparatus can comprise the signature determination apparatus.

In a further aspect of the present invention a power consumption monitoring method for monitoring the power consumed in a network of electrical devices is presented, wherein the power consumption monitoring method comprises:
measuring an overall electrical parameter of the network over time by an electrical parameter measuring unit,
providing group signatures by a group signature providing unit, wherein each group signature is indicative of an electrical parameter of a certain group of electrical devices over time,
disaggregating the measured overall electrical parameter over time for determining the power consumption of the individual groups of electrical devices depending on the provided group signatures by a disaggregation unit.

In a further aspect of the present invention a signature determination method for determining signatures to be used by a power consumption monitoring apparatus is presented, wherein the signature determination method comprises:
measuring an electrical parameter over time by an electrical parameter measuring unit separately for different groups of electrical devices of a network of electrical devices such that for each group the electrical parameter over time is measured,
determining group signatures for the groups of electrical devices based on the electrical parameter measured over time for the respective group of electrical devices by a group signature determination unit.

In a further aspect of the present invention a power consumption monitoring computer program for monitoring the power consumed in a network of electrical devices is presented, wherein the power consumption computer program comprises program code means for causing a power consumption monitoring apparatus as defined in claim 1 to carry out following steps:
providing group signatures by a group signature providing unit, wherein each group signature is indicative of an electrical parameter of a certain group of electrical devices over time,
disaggregating a measured overall electrical parameter over time for determining the power consumption of the individual groups of electrical devices depending on the provided group signatures by a disaggregation unit.

In a further aspect of the present invention a signature determination computer program for determining signatures to be used by a power consumption monitoring apparatus is presented, wherein the signature determination computer program comprises program code means for causing a signature determination apparatus as defined in claim 9 to carry out following steps:
measuring an electrical parameter over time by an electrical parameter measuring unit separately for different groups of electrical devices of a network of electrical devices such that for each group the electrical parameter over time is measured,
determining group signatures for the groups of electrical devices based on the electrical parameter measured over time for the respective group of electrical devices by a group signature determination unit.

It shall be understood that the power consumption monitoring apparatus of claim 1, the signature determination apparatus of claim 7, the power consumption monitoring method of claim 12, the signature determination method of claim 13, the power consumption monitoring computer program of claim 14, and the signature determination computer program of claim 15 have similar and/or identical preferred embodiments, in particular, as defined in the dependent claims.

It shall be understood that a preferred embodiment of the invention can also be any combination of the dependent claims with the respective independent claim.

These and other aspects of the invention will be apparent from and elucidated with reference to the embodiments described hereinafter.

### BRIEF DESCRIPTION OF THE DRAWINGS

In the drawings:

FIG. 1 shows schematically and exemplarily an electrical network of electrical devices comprising a power source and a power consumption monitoring apparatus,

FIG. 2 shows schematically and exemplarily an embodiment of the power consumption monitoring apparatus,

FIG. 3 shows schematically and exemplarily the electrical network connected to a signature determination apparatus,

FIG. 4 shows schematically and exemplarily group signatures of a first group of electrical devices of the network,

FIG. 5 shows schematically and exemplarily group signatures of a second group of electrical devices of the network,

FIG. 6 shows schematically and exemplarily the overall consumed power and the power consumed by the first group,

FIG. 7 shows schematically and exemplarily the overall consumed power and the power consumed by the second group,

FIG. 8 shows a flowchart exemplarily illustrating an embodiment of a signature determination method for determining signatures to be used by the power consumption monitoring apparatus, and

FIG. 9 shows a flowchart exemplarily illustrating an embodiment of a power consumption monitoring apparatus for monitoring the power consumed in the network of electrical devices.

### DETAILED DESCRIPTION OF EMBODIMENTS

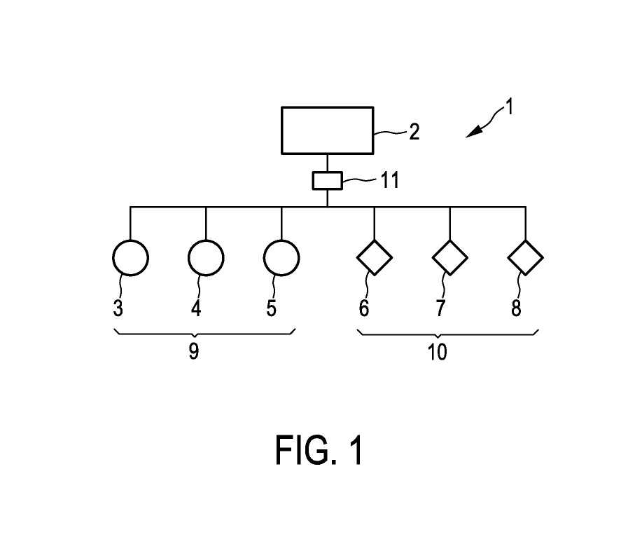

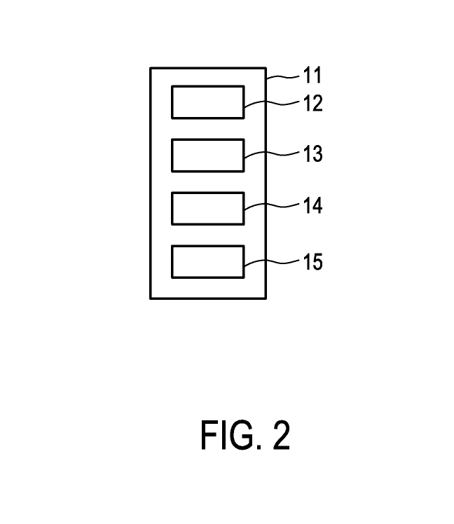

FIG. 1 shows schematically and exemplarily an electrical network 1 of electrical devices 3 . . . 8, which are powered by a power source 2. The electrical network 1 of electrical devices 3 . . . 8 comprises a power consumption monitoring apparatus 11 for monitoring the power consumed in the electrical network 1, which is schematically and exemplarily shown in more detail in FIG. 2.

The power consumption monitoring apparatus 11 comprises an electrical parameter measuring unit 12 for measuring an overall electrical parameter of the electrical network 1 over time. In this embodiment, the electrical parameter measuring unit 12 is adapted to measure the overall electrical current of the electrical network 1 over time. The power consumption monitoring apparatus 11 further comprises a group signature providing unit 13 for providing group signatures, wherein each group signature is indicative of an electrical parameter of a certain group of electrical devices over time. In this embodiment, the electrical network 1 comprises a first group 9 containing the electrical devices 3, 4, 5 and a second group 10 containing the electrical devices 6, 7, 8. The power consumption monitoring apparatus 11 also comprises a disaggregation unit 14 for disaggregating the measured overall electrical parameter, i.e. this embodiment the overall electrical current, over time for determining the power consumption of the individual groups 9, 10 of the electrical devices depending on the provided group signatures. The disaggregation unit 14 uses a NILM technique for a sub-metering application to separate different technical groups and not for separating different electrical devices, i.e. different appliances. The power consumption monitoring apparatus 11 further comprises an output unit 15 for outputting the determined power consumption of the individual groups 9, 10 of electrical devices to a user or to another device. In this embodiment, the output unit 15 is a display for displaying the determined power consumption of the individual groups to the user.

Each group 9, 10 of electrical devices contains a certain kind of electrical devices. For instance, in this embodiment the first group 9 of electrical devices comprises electrical devices 3, 4, 5, which are electrically connected to sockets of a building, and the second group 10 of electrical devices 6, 7, 8 comprises lamps, which are not electrically connected to a socket.

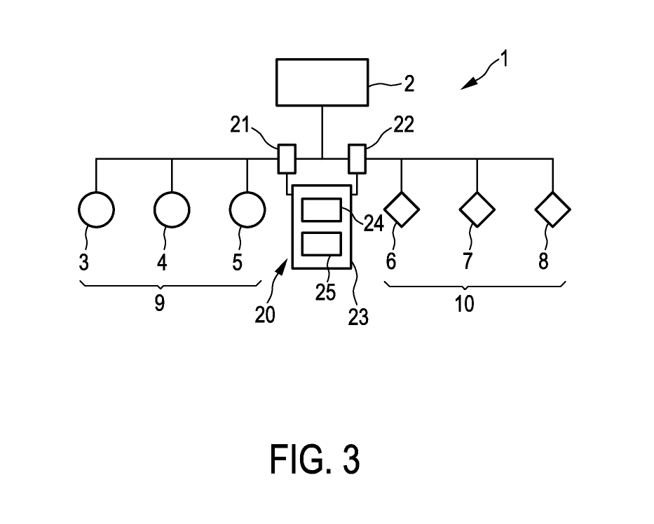

The electrical parameter measuring unit 12 is adapted to measure the overall electrical parameter at a single point of measurement, wherein the disaggregation unit 14 is adapted to disaggregate the measured overall electrical parameter measured at the single point of measurement. Moreover, in this embodiment the electrical devices 3 . . . 8 are powered by using AC voltage provided by the power source 2, wherein the used AC voltage defines AC periods. The group signatures provided by the group signature providing unit 13 are preferentially indicative of the electrical parameter over an AC period, wherein the disaggregation unit 14 is adapted to determine the power consumed in an AC period by disaggregating the measured overall electrical parameter over the AC period depending on the provided group signatures. In this embodiment, the group signatures are electrical currents measured for the respective group 9, 10 over an AC period, wherein the disaggregation unit 14 is adapted to determine the power consumed in an AC period by disaggregating the measured overall electrical current over the AC period depending on the provided group signatures. The group signatures can be determined in a training phase by using a signature determination apparatus. This will in the following be described with reference to FIG. 3.

FIG. 3 shows schematically and exemplarily the electrical network 1 of electrical devices 3 . . . 8 powered by the power source 2 together with the signature determination apparatus 20 for determining signatures to be used by the power consumption monitoring apparatus 11. The signature determination apparatus 20 comprises an electrical parameter measuring unit 21, 22 for measuring an electric parameter over a time separately for the different groups 9, 10 of electrical devices of the network 1, in order to measure for each group 9, 10 the electrical parameter over time. In this embodiment, the electrical parameter measuring unit comprises two electrical current measuring units 21, 22, which are electrically connected to each respective group 9, 10 of electrical devices, for measuring separately for each group 9, 10 the electrical current over time. The signature determination apparatus 20 further comprises a group signature determination unit 24 for determining the group signatures for the groups 9, 10 of electrical devices based on the electrical parameter measured over time for the respective group 9, 10 of electrical devices. Moreover, the signature determination apparatus 23 comprises a storing unit 25, in particular a database, in which the determined group signatures are stored. The stored group signatures can be provided to the power consumption monitoring apparatus 11, in particular to the group signature providing unit 13, which may also be a storing unit, for allowing the group signature providing unit 13 to provide the group signatures.

The group signature determination 24 and the storing unit 25 can be integrated into a single processing unit 23. However, these units can also be arranged in different housings.

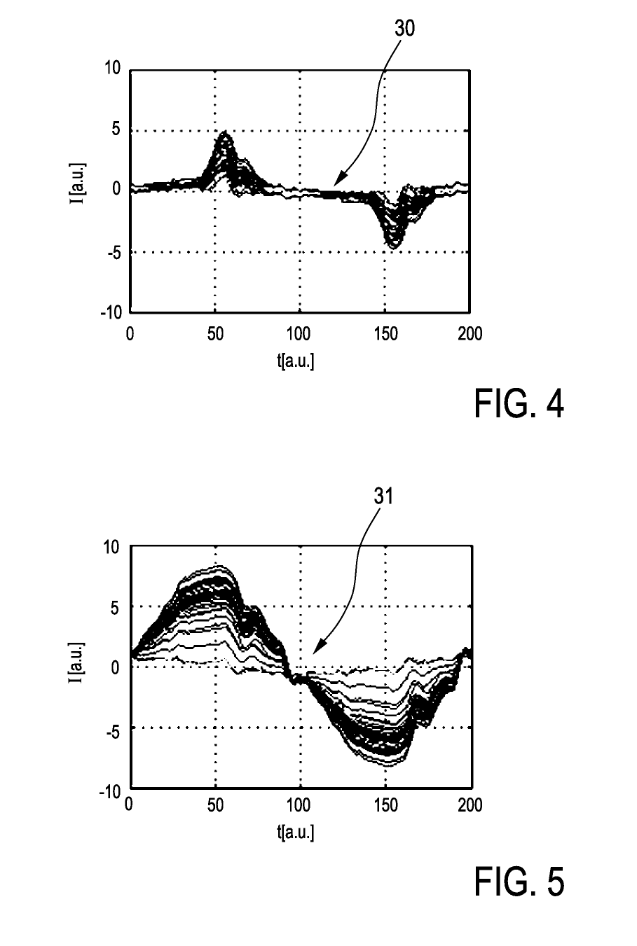

The electrical parameter measuring unit 21, 22 is preferentially adapted to measure for each group 9, 10 the electrical current over the AC periods, in order to determine for each group 9, 10 current cycles which correspond to an AC period, wherein the group signature determination unit 14 is adapted to determine the group signatures of a group 9, 10 from the current cycles measured for the respective group 9, 10. FIG. 4 shows schematically and exemplarily group signatures 30 for an AC period for the first group 9, wherein I indicates the electrical current and t indicates the time. FIG. 5 shows schematically and exemplarily group signatures 31 for an AC period determined for the second group 10. The group signatures shown in these figures are current signatures in an office of one day. It can be seen in FIG. 5 that the second group 10 corresponds to many light sources of the same type, because the group signatures have the same shape, but different amplitudes.

The group signature determination unit 24 is preferentially adapted to select from the current cycles, which have been measured for the respective group 9, 10, current cycles, which should be used for determining the group signatures for the respective group 9, 10, depending on differences between the current cycles measured for the respective group 9, 10. In particular, the group signature determination unit 24 is adapted to select the current cycles to be used for determining the group signatures for the respective group 9, 10 such that for each current cycle measured for the respective group 9, 10 the difference between the respective measured current cycle and at least one selected current cycle is smaller than a difference threshold. For instance, if each current cycle is sampled with K samples per AC period, each measured current cycle of a respective group can be seen as a point in a corresponding K-dimensional space. If a large number of N current cycles have been measured for a respective group 9, 10 of electrical devices, these measured current cycles may correspond to N distinct points in the K-dimensional space, even if the network of electrical devices is stable, because of measurement noise. In order to reduce this large number of measured current cycles, the group signature determination unit 24 preferentially selects a smaller number of current cycles to be used for determining the group signatures. For example, in the K-dimensional space, the concept of distance between points can be introduced, wherein the Euclidean distance is preferred. Given a difference threshold E, a set of points S can be determined, for example, as follows. The N measured current cycles can be denoted by C₁ . . . C_{N}. The set of points S can be initialized to be an empty set and initially a variable n can be set to one. Then, considering Cₙ, it can be searched for the point in the set of points S, which is closest to the current cycle Cₙ. If such a closest point exists in the set of points S and if its distance to the current cycle Cₙ is less than the difference threshold E, the set of points S is not modified, otherwise the current cycle Cₙ is added to the set of points S. The variable n is then incremented by one and these steps are repeated, until all measured current cycles C₁ . . . Cₙ have been considered. The group signature determination unit 24 can further be adapted to compare the resulting number of points in the set of points S with a predefined number threshold and to repeat the entire procedure of selecting the current cycles from all measured current cycles with a larger difference threshold E for reducing the number of group signatures determined for a respective group.

The group signature determination unit 24 can therefore be adapted to select current cycles that are different enough from each other such that the number of current cycles is reduced to a tractable number. In particular, the group signature determination unit 24 is adapted to select for each group of electrical devices a number of current cycles that represent well enough the entire group signature space of the respective group.

The group signature determination unit 24 can be adapted to divide the measured current cycles by the AC voltage, wherein in this case, during the disaggregation, also the measured overall electrical current is divided by the AC voltage, in order to deal with possible voltage variations, thereby allowing for an improvement of the accuracy of the disaggregation.

The disaggregation unit 14 is preferentially adapted to disaggregate the measured overall electrical current by combining group signatures 30, 31 of the different groups 9, 10 such that a deviation between a resulting combination of group signatures 30, 31 and the measured overall electrical current is minimized. Thus, one of the group signatures 30 is combined with one of a group signature 31 such that a deviation between this combined electrical current and the overall electrical current is minimized. For instance, the combination of the group signatures of the different groups 9, 10 can be an integer linear combination, wherein the integer linear combination can be determined such that a deviation measure applied to the integer linear combination and the measured overall electrical parameter yields a minimized deviation. The deviation measure is, for instance, a squared difference between the measured overall electrical parameter and the integer linear combination, wherein differences between corresponding electrical parameter values of the respective integer linear combination and the measured overall electrical parameter can be calculated, squared and summed for determining the deviation. Corresponding electrical parameter values are, for instance, values that have the same temporal position within an AC period. Based on the combination of group signatures, which minimizes the deviation, the disaggregation unit 14 can easily determine the power consumption of the respective group 9, 10 of electrical devices. For example, if the group signatures represent an electrical current over an AC period, a respective group signature, which is part of the resulting combination that minimizes the deviation, multiplied with the respective linear coefficient can be multiplied with the AC voltage for determining the power consumption of the respective group of electrical devices.

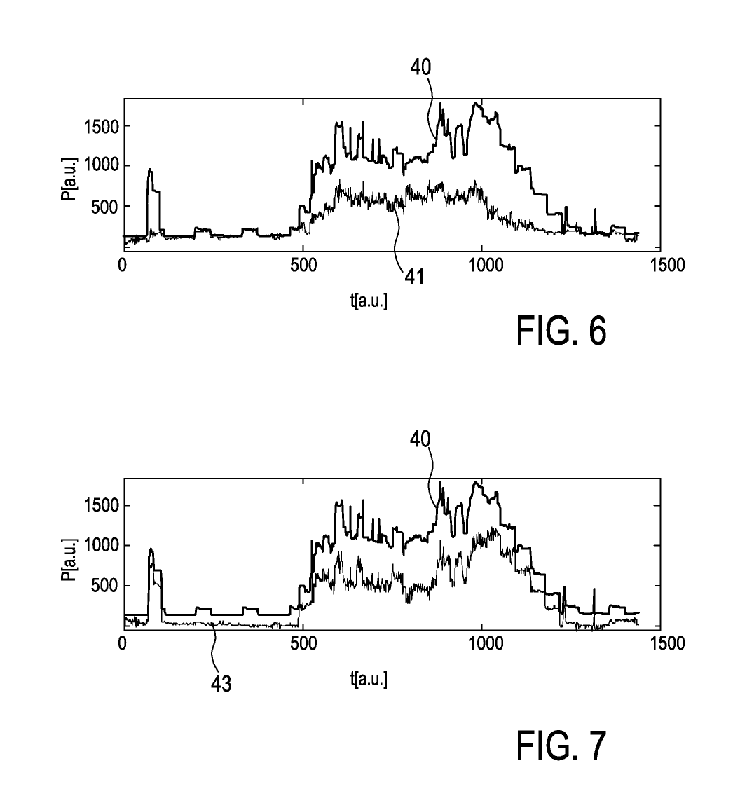

FIG. 6 shows schematically and exemplarily a disaggregation result determined by the disaggregation unit 14 for the first group and FIG. 7 shows schematically and exemplarily a disaggregation result determined by the disaggregation unit 14 for the second group 10. In these figures, reference number 40 indicates the total power over time, reference number 41 indicates the determined power consumption of the first group 9 as provided by the disaggregation unit 14, and reference number 43 indicates the determined power consumption of the second group 10 as provided by the disaggregation unit 14.

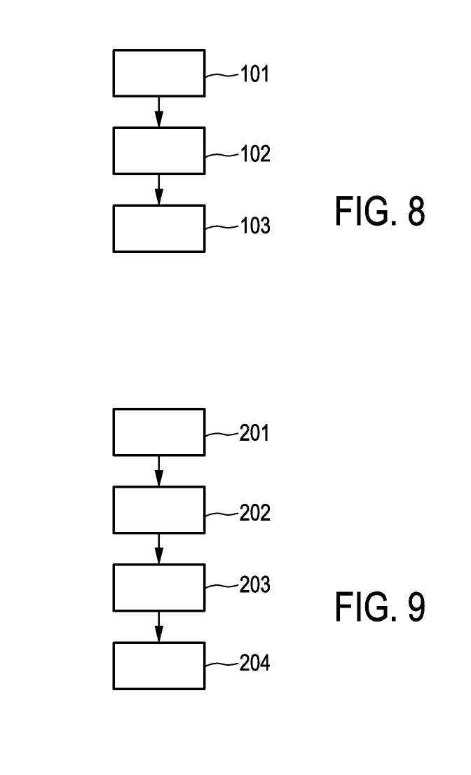

FIG. 8 shows a flowchart exemplarily illustrating an embodiment of a signature determination method for determining signatures to be used by the power consumption monitoring apparatus.

In step 101, an electrical parameter is measured over time by the electrical parameter measuring unit 21, 22 separately for the different groups 9, 10 of the electrical devices of the network 1 such that for each group 9,10 the electrical parameter over time is measured. In this embodiment, the electrical parameter is the electrical current consumed by the respective group 9, 10 measured over different AC periods such that for each group 9, 10 several current cycles are measured.

In step 102, group signatures are determined for the groups 9, 10 of electrical devices based on the electrical parameter measured over time for the respective group 9, 10 of electrical devices by the group signature determination unit 24. For instance, from the current cycles measured for the respective group 9, 10 some current cycles are selected as the group signatures of the respective group 9, 10. In step 103, the determined group signatures are stored in the storing unit 25.

The signature determination apparatus can be adapted to monitor each group of electrical devices individually and to extract the current cycles, i.e. the current waveforms during an AC period of the AC voltage, that characterize this specific group. The proposed procedure preferentially collects the cycles that are different enough from each other and then reduces them to a tractable number. Preferentially, a few numbers of cycles that represent well enough the entire signature space of the group is selected. Each representative cycle, which forms a group signature, is preferentially sampled at a high enough rate of, for instance, 200 samples per period. At the end of the training phase a local database that characterizes the respective group is available, i.e. for each group a set of current cycles forming the group signatures is preferentially available and stored in a local database. The training may require some time, for instance, one typical day. This time may be required to ensure that all aggregated consumption patterns of the appliances, i.e. of the electrical devices, of the respective group are captured by the group signatures of the respective group.

The signatures determination method can therefore be regarded as being performed during a training phase, in which the disaggregation technique is trained to the actual network 1 of electrical devices. After this training has been completed, i.e. after the group signatures have been determined, a power consumption monitoring method for monitoring the power consumed in the network 1 of electrical devices can be performed as will be illustrated in the following with reference to a flowchart shown in FIG. 9.

In step 201, an overall electrical parameter of the network 1 is measured over time by the electrical parameter measuring unit 12. In particular, the overall electrical current is measured over time at a single point of measurement. In step 202, the group signatures are provided by the group signature providing unit 13, wherein each group signature is indicative of an electrical parameter of a certain group 9, 10 of the electrical devices over time. In this embodiment, the group signature providing unit 13 is a storing unit, in which the group signatures, which have been determined by the signature determination apparatus 1, are stored for providing the same, when required during a power consumption monitoring process. The group signatures are preferentially electrical currents measured over an AC period of AC voltage supplied by the power source 2.

In step 203, the measured overall electrical parameter over time is disaggregated by the disaggregation unit 14 for determining the power consumption of the individual groups 9, 10 of the electrical devices depending on the provided group signatures. For instance, for a certain AC period a group signature of the first group and a group signature of the second group can be combined such that a deviation between the measured overall current and the combination is minimized, wherein the actual power consumed by the first group 9 and the second group 10 can be determined based on this combination of group signatures. In step 204, the power consumption determined for the individual groups 9, 10 can be shown on the display 15.

Thus, after the group signatures have been determined, the disaggregation algorithm performed by the disaggregation unit 14 preferentially looks at the overall current and recognizes the contributions of the different groups in the overall electricity consumption, wherein one possible solution consists of finding the combination of group signatures in the different groups that minimizes the distance to the observed overall electrical current.

The disaggregation algorithm treats the groups preferentially like complex multi-state appliances. For example, if a group comprises two appliances, i.e. two electrical devices, that can only be switched on or off, in the training phase for this group, three group signatures may be generated corresponding to the following states: a) first electrical device on, second electrical device off; b) first electrical device off, second electrical device on; and c) first electrical device on, second electrical device on, wherein it is assumed that, when both electrical devices are off, they do not carry any current.

The disaggregation unit 14 is preferentially adapted to use a NILM algorithm for determining the power consumption of the different electrical groups, without determining the power consumption of individual electrical devices of the respective group.

Although in the above described embodiments the power consumption monitoring apparatus and the signature determination apparatus have been described as being two separate apparatuses, in other embodiments the signature determination apparatus can also be integrated into the power consumption monitoring apparatus, wherein, for instance, the storing unit for storing the determined group signatures and the group signature providing unit for providing the group signatures for performing an actual disaggregation procedure can be the same unit.

Although in above described embodiments certain groups of electrical devices are mentioned, in other embodiments the power consumption monitoring apparatus can be adapted to determine the power consumption of other individual groups of electrical devices, in particular, depending on how the electrical network is setup.

Although in above described embodiments the power consumption monitoring apparatus is adapted to determine the power consumption of two individual groups of electrical devices, the power consumption monitoring apparatus can of course also be adapted to determine the power consumption of more than two individual groups of electrical devices. The different groups of electrical devices can be defined, for instance, depending on their location, in particular, within a building. For example, electrical devices within a certain room of a building can form a group of electrical devices.

Although in an above described embodiment group signatures are combined to an integer linear combination for disaggregating the measured overall parameter, in other embodiments the group signatures can also be combined in another way. For instance, another kind of linear combination can be used, wherein some or all coefficients of the linear combination may not be restricted to integer values. For example, the coefficients in the linear combination may be restricted to integer values for some group signatures, while they may take any value for other group signatures, in particular in the case of dimmable lights, if not every fine grained dimming level is stored in a signature database.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single unit or device may fulfill the functions of several items recited in the claims. The mere fact that certain measures are recited in mutually different dependent claims does not indicate that a combination of these measures cannot be used to advantage.

Procedures like the determination and/or provision of group signatures or like the disaggregation procedure performed by one or several units or devices can be performed by any other number of units or devices. For example, steps 102 and 103 and steps 202 and 203 can be performed by a single unit or by any other number of different units. The procedures and/or the control of the power consumption monitoring apparatus in accordance with the power consumption monitoring method and/or the control of the signature determination apparatus in accordance with the signature determination method can be implemented as program code means of a computer program and/or as dedicated hardware.

A computer program may be stored/distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

The invention relates to a power consumption monitoring apparatus for monitoring the power consumed in a network of electrical devices. An electrical parameter measuring unit measures an overall electrical parameter of the network over time, a group signature providing unit provides group signatures, wherein each group signature is indicative of an electrical parameter of a certain group of electrical devices over time, and a disaggregation unit disaggregates the measured overall electrical parameter over time for determining the power consumption of the individual groups of electrical devices depending on the provided group signatures. This allows disaggregating the overall electrical parameter, without providing for each group an individual measuring unit, thereby reducing the required hardware and the time needed for installing and maintaining the power consumption monitoring apparatus.

1. A power consumption monitoring apparatus for monitoring the power consumed in a network of electrical devices, wherein the power consumption monitoring apparatus comprises:
an electrical parameter measuring unit for measuring an overall electrical parameter of the network over time,
a group signature providing unit for providing group signatures, wherein each group signature is indicative of an electrical parameter of a certain group of electrical devices over time,
a disaggregation unit for disaggregating the measured overall electrical parameter over time for determining the power consumption of the individual groups of electrical devices depending on the provided group signatures

2. The power consumption monitoring apparatus as defined in claim 1, wherein the electrical parameter measuring unit is adapted to measure the overall electrical parameter at a single point of measurement and wherein the disaggregation unit is adapted to disaggregate the measured overall electrical parameter measured at the single point of measurement.

3. The power consumption monitoring apparatus as defined 1, wherein the electrical devices are powered by using AC voltage defining AC periods, wherein the group signatures are indicative of the electrical parameter over an AC period and wherein the disaggregation unit is adapted to determine the power consumed in an AC period by disaggregating the measured overall electrical parameter over the AC period depending on the provided group signatures.

4. The power consumption monitoring apparatus as defined in claim 1, wherein the disaggregation unit is adapted to disaggregate the measured overall electrical parameter by combining group signatures of different groups such that a deviation between a resulting combination of group signatures and the measured overall electrical parameter is minimized.

5. The power consumption monitoring apparatus as defined in claim 1, wherein the electrical parameter measured over time is the electrical current.

6. The power consumption monitoring apparatus as defined in claim 1, wherein the power consumption monitoring apparatus comprises a signature determination apparatus as defined in claim 7.

7. A signature determination apparatus for determining signatures to be used by a power consumption monitoring apparatus, wherein the signature determination apparatus comprises:
an electrical parameter measuring unit for measuring an electrical parameter over time separately for different groups of electrical devices of a network of electrical devices in order to measure for each group the electrical parameter over time,
a group signature determination unit for determining group signatures for the groups of electrical devices based on the electrical parameter measured over time for the respective group of electrical devices.

8. The signature determination apparatus as defined in claim 7, wherein the electrical devices of the network (1) are powered by using AC voltage defining AC periods, wherein the electrical parameter measuring unit is adapted to measure for each group the electrical parameter over the AC periods, in order to determine for each group current cycles which correspond to an AC period, wherein the group signature determination unit is adapted to determine the group signatures of a group from the current cycles measured for the respective group.

9. The signature determination apparatus as defined in claim 8, wherein the group signature determination unit is adapted to select from the current cycles measured for the respective group current cycles to be used for determining the group signatures for the respective group depending on differences between the current cycles measured for the respective group.

10. The signature determination apparatus as defined in claim 9, wherein the group signature determination unit is adapted to select the current cycles to be used for determining the group signatures for the respective group such that for each current cycle measured for the respective group the difference between the respective measured current cycle and at least one selected current cycle is smaller than a difference threshold.

11. The signature determination apparatus as defined in claim 8, wherein the group signature determination unit is adapted to divide the measured current cycles by the AC voltage.

12. A power consumption monitoring method for monitoring the power consumed in a network of electrical devices, wherein the power consumption monitoring method comprises:
measuring an overall electrical parameter of the network over time by an electrical parameter measuring unit,
providing group signatures by a group signature providing unit, wherein each group signature is indicative of an electrical parameter of a certain group of electrical devices over time,
disaggregating the measured overall electrical parameter over time for determining the power consumption of the individual groups of electrical devices depending on the provided group signatures by a disaggregation unit.

13. A signature determination method for determining signatures to be used by a power consumption monitoring apparatus, wherein the signature determination method comprises:
measuring an electrical parameter over time by an electrical parameter measuring unit separately for different groups of electrical devices of a network of electrical devices such that for each group the electrical parameter over time is measured,
determining group signatures for the groups of electrical devices based on the electrical parameter measured over time for the respective group of electrical devices by a group signature determination unit.

14. A power consumption monitoring computer program for monitoring the power consumed in a network of electrical devices, the power consumption computer program comprising program code means for causing a power consumption monitoring apparatus as defined in claim 1 to carry out following steps:
providing group signatures by a group signature providing unit, wherein each group signature is indicative of an electrical parameter of a certain group of electrical devices over time,
disaggregating a measured overall electrical parameter over time for determining the power consumption of the individual groups of electrical devices depending on the provided group signatures by a disaggregation unit.

15. A signature determination computer program for determining signatures to be used by a power consumption monitoring apparatus, the signature determination computer program comprising program code means for causing a signature determination apparatus as defined in claim 9 to carry out following steps:
measuring an electrical parameter over time by an electrical parameter measuring unit separately for different groups of electrical devices of a network of electrical devices such that for each group the electrical parameter over time is measured,
determining group signatures for the groups of electrical devices based on the electrical parameter measured over time for the respective group of electrical devices by a group signature determination unit.
